(19) United States
(12) Patent Application Publication
(10) Pub. No.: US 2024/0263305 A1
(43) Pub. Date: Aug. 8, 2024

(54) RAW MATERIAL GAS SUPPLY SYSTEM, POWDER RAW MATERIAL REPLENISHING MECHANISM, AND POWDER RAW MATERIAL REPLENISHING METHOD

(71) Applicant: Tokyo Electron Limited, Minato-ku, Tokyo (JP)

(72) Inventor: Eiichi KOMORI, Nirasaki City, Yamanashi (JP)

(21) Appl. No.: 18/565,099

(22) PCT Filed: May 18, 2022
(86) PCT No.: PCT/JP2022/020650

§ 371 Date: Nov. 29, 2023

(30) Foreign Application Priority Data
Jun. 1, 2021 (JP) 2021-092169

(51) Int. Cl. C23C 16/448; C23C 16/455

(52) U.S. Cl. CPC C23C 16/4481; C23C 16/45544

(57) ABSTRACT

A powder raw material replenishing mechanism for replenishing a powder raw material to a powder raw material supply apparatus includes: a pipe having one end connected to the powder raw material supply apparatus; a powder raw material cartridge filled with the powder raw material; a connector provided at the other end of the pipe such that the powder raw material cartridge is detachably connected to the connector; an opening/closing part provided in the pipe to open and close between the pipe and the powder raw material cartridge; and a vacuum exhauster for evacuating the pipe to keep the interior of the pipe at a vacuum. In such a vacuum state, the powder raw material cartridge is connected to the connector and the opening/closing part is opened so that the powder raw material inside the powder raw material cartridge is transferred to the powder raw material supply apparatus.

### TECHNICAL FIELD

The present disclosure relates to a raw material gas supply system, a powder raw material replenishing mechanism, and a powder raw material replenishing method.

### BACKGROUND

Patent Document 1 discloses a raw material gas supply system including a vaporization apparatus that receives and vaporizes a powder raw material, a raw material gas supply pipe that supplies a raw material gas generated by the vaporization apparatus to a processing apparatus, and a powder raw material supply apparatus (replenishing apparatus) that supplies the powder raw material to the vaporization apparatus. In Patent Document 1, the supply apparatus (replenishing apparatus) is configured such that a raw material cartridge filled with the powder raw material is detachably attached to the supply apparatus.

### PRIOR ART DOCUMENT

### Patent Document

Patent Document 1: Japanese Laid-Open Patent Publication No. 2020-180354

The present disclosure provides a technology capable of replenishing a powder raw material to a powder raw material supply apparatus that supplies the powder raw material to a vaporization apparatus, without exposure to atmosphere.

### SUMMARY

According to one aspect of the present disclosure, a powder raw material replenishing mechanism for replenishing a powder raw material to a powder raw material supply apparatus that supplies the powder raw material to a vaporization apparatus in a raw material gas supply system that supplies a raw material gas, generated by vaporizing the powder raw material with the vaporization apparatus, to a processing apparatus, includes: a pipe having one end connected to the powder raw material supply apparatus; a powder raw material cartridge filled with the powder raw material; a connector provided at a side of the other end of the pipe such that the powder raw material cartridge is detachably connected to the connector; an opening/closing part provided at the side of the other end of the pipe and configured to open and close between the pipe and the powder raw material cartridge; and a vacuum exhauster configured to evacuate an interior of the pipe and keep the interior of the pipe at a vacuum. In a state where the interior of the pipe is kept at the vacuum by the vacuum exhauster, the powder raw material cartridge is connected to the connector, and the opening/closing part is opened in the state so that the powder raw material inside the powder raw material cartridge is transferred to the powder raw material supply apparatus.

According to the present disclosure, it is possible to provide a technology capable of replenishing a powder raw material to a powder raw material supply apparatus that supplies the powder raw material to a vaporization apparatus, without exposure to the atmosphere.

### BRIEF DESCRIPTION OF DRAWINGS

FIG. 1 is a schematic diagram illustrating an example of a configuration of a raw material gas supply system including a powder raw material replenishing mechanism according to an embodiment.

FIG. 2 is a diagram illustrating a schematic configuration of a powder raw material supply apparatus in the raw material gas supply system of FIG. 1.

FIG. 3 is a cross-sectional view illustrating a specific example of the powder raw material replenishing mechanism.

FIG. 4 is a cross-sectional view illustrating a state where an opening/closing part is open to transfer a powder raw material from a powder raw material cartridge in the powder raw material replenishing mechanism.

FIG. 5 is a diagram illustrating an example of an operation state of the raw material gas supply system of FIG. 1.

FIG. 6 is a cross-sectional view illustrating another embodiment of the powder raw material replenishing mechanism.

FIG. 7 is a cross-sectional view illustrating still another embodiment of the powder raw material replenishing mechanism.

FIG. 8 is a cross-sectional view illustrating another example of the opening/closing part of the powder raw material replenishing mechanism.

### DETAILED DESCRIPTION

Hereinafter, embodiments will be described with reference to the accompanying drawings.

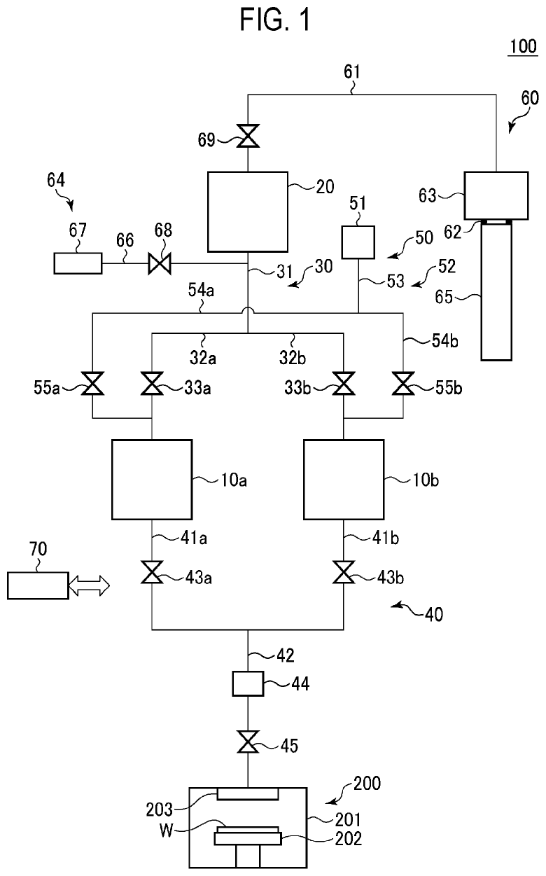

FIG. 1 is a schematic diagram illustrating an example of a configuration of a raw material gas supply system including a powder raw material replenishing mechanism according to an embodiment. A raw material gas supply system 100 vaporizes a powder raw material and supplies a raw material gas thus generated to a processing apparatus 200.

As illustrated in FIG. 1, the processing apparatus 200 includes a processing container 201 whose interior is capable of being kept at a vacuum, a stage 202 provided inside the processing container 201 to place a substrate W thereon, and a gas introducer 203 for introducing a raw material gas into the processing container 201. The processing apparatus 200 performs a specific processing, for example, a film formation processing on the substrate W by introducing the raw material gas supplied from the raw material gas supply system 100 into the processing container 201. Examples of the film forming processing may include CVD and ALD. Further, the processing apparatus 200 is configured to be able to introduce not only the raw material gas but also a reaction gas and an inert gas into the processing container from the gas introducer 203. For example, a WCl⁶ gas may be supplied as the raw material gas so that a tungsten film is formed on the substrate W. A semiconductor wafer is given as an example of the substrate W.

The raw material gas supply system 100 includes two vaporization apparatuses 10a and 10b, a powder raw material supply apparatus 20, a powder raw material supply piping section 30, a raw material gas supply piping section 40, a carrier gas supplier 50, a powder raw material replenishing mechanism 60, and a controller 70.

The vaporization apparatuses 10a and 10b store a powder raw material such as WCl₆ supplied thereto and vaporize (sublimate) the stored powder raw material to generate a raw material gas. Each of the vaporization apparatuses 10a and 10b includes a container for storing the powder raw material. The vaporization of the powder raw material may be performed by, for example, heating the container with a heater in a state where the powder raw material stored in the container. The vaporization apparatuses 10a and 10b are provided in parallel to the processing apparatus 200. As will be described later, the vaporization apparatuses 10a and 10b may be configured such that the powder raw material is supplied to one apparatus while the other apparatus vaporizes the powder raw material by the operation of on-off valves.

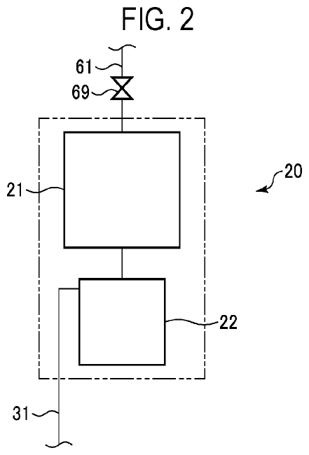

The powder raw material supply apparatus 20 store the powder raw material and supply the powder raw material to the vaporization apparatus 10a or 10b. For example, as illustrated in FIG. 2, the powder raw material supply apparatus 20 includes a storage container 21 for storing the powder raw material and a feeder 22 for delivering the powder raw material from the storage container 21. The storage container 21 may take the form of, for example, a hopper. The feeder 22 may be, for example, a vibration feeder.

The powder raw material supply piping section 30 includes a common pipe 31 having one end connected to the powder raw material supply apparatus 20, and branch pipes 32a and 32b branched at the other end of the common pipe 31 to reach the vaporization apparatuses 10a and 10b, respectively. The branch pipes 32a and 32b are provided with on-off valves 33a and 33b, respectively. By opening and closing the on-off valves 33a and 33b, the supply and cutoff of the powder raw material from the powder raw material supply apparatus 20 to the vaporization apparatuses 10a and 10b may be performed.

The raw material gas supply piping section 40 supplies the raw material gas, generated by vaporizing the powder raw material in the vaporization apparatuses 10a and 10b, to the processing apparatus 200, and includes individual pipes 41a and 41b, and a common pipe 42. The individual pipes 41a and 41b extend from the vaporization apparatuses 10a and 10b, respectively, and are joined with each other. The common pipe 42 extends from the join point to the processing apparatus 200. The individual pipes 41a and 41b are provided with on-off valves 43a and 43b, respectively. By opening and closing the on-off valves 43a and 43b, the supply and cutoff of the raw material gas from the vaporization apparatuses 10a and 10b to the processing apparatus 200 may be performed. The common pipe 42 is equipped with a flow meter 44 such as a mass flow meter (MFM), an on-off valve 45, and the like.

The carrier gas supplier 50 supplies a carrier gas for transferring the raw material gas, generated by the vaporization apparatuses 10a and 10b, to the processing apparatus 200, and includes a carrier gas source 51 and a carrier gas supply piping section 52. The carrier gas supply piping section 52 includes a common pipe 53 having one end connected to the carrier gas source 51 and branch pipes 54a and 54b branched at the other end of the common pipe 53. End portions of the branch pipes 54a and 54b are connected to the branch pipes 32a and 32b of the powder raw material supply piping section 30 at the downstream side of the on-off valves 33a and 33b, respectively. The branch pipes 54a and 54b are provided with on-off valves 55a and 55b, respectively. The on-off valve 55a is open when supplying the raw material gas from the vaporization apparatus 10a to the processing apparatus 200, and the on-off valve 55b is open when supplying the raw material gas from the vaporization apparatus 10b to the processing apparatus 200.

The powder raw material replenishing mechanism 60 replenishes the powder raw material to the powder raw material supply apparatus 20, and includes a pipe 61, a connector 62, an opening/closing part 63, a vacuum exhauster 64, and a powder raw material cartridge 65.

The pipe 61 has one end connected to the powder raw material supply apparatus 20. The connector 62 is provided at the side of the other end of the pipe 61, and the powder raw material cartridge 65 is detachably connected to the connector 62. A connection port of the connector 62 is oriented downward. The opening/closing part 63 is provided at the side of the other end of the pipe 61 to open and close between the pipe 61 and the powder raw material cartridge 65, so that the supply and cutoff of the powder raw material from the powder raw material cartridge 65 to the powder raw material supply apparatus 20 is performed. The connector 62 is provided on a bottom surface of the opening/closing part 63.

The vacuum exhauster 64 has a function of evacuating an interior of the pipe 61 from the side of the powder raw material supply apparatus 20 to keep the interior of the pipe 61 at a vacuum. The vacuum exhauster 64 includes an exhaust pipe 66 connected to the common pipe 31, an exhaust device 67 such as a vacuum pump connected to the exhaust pipe 66, and a valve 68 provided in the exhaust pipe 66, and is configured to evacuate the interior of the pipe 61 via the powder raw material supply apparatus 20. By opening the opening/closing part 63 with the interior of the pipe 61 evacuated by the vacuum exhauster 64, the powder raw material is drawn from the powder raw material cartridge 65 and is transferred to the powder raw material supply apparatus 20. The vacuum exhauster 64 is provided with a bypass pipe (not illustrated) that bypasses and discharges the powder raw material of the powder raw material supply apparatus 20 if air presents in the interior of the pipe 61. In addition, an on-off valve 69 is provided at the side of one end of the pipe 61.

The powder raw material cartridge 65 contains the powder raw material and an inert gas functioning as a carrier gas and includes an on-off valve (not illustrated in FIG. 1) provided at one end thereof and a connection surface connected to the connector 62. The connector 62 has a seal structure, and the connection surface of the powder raw material cartridge 65 is in close contact with the connector 62. Further, the powder raw material inside the powder raw material cartridge 65 is unloaded while being carried by the inert gas when the on-off valve is open.

In addition, FIG. 1 illustrates an example in which the opening/closing part 63 is provided at the other end of the pipe 61 and the connector 62 of the powder raw material cartridge 65 is provided at the opening/closing part 63, but the opening/closing part 63 may be provided in the pipe 61 rather than at the other end of the pipe 61 and the connector 62 may be provided at the other end of the pipe 61.

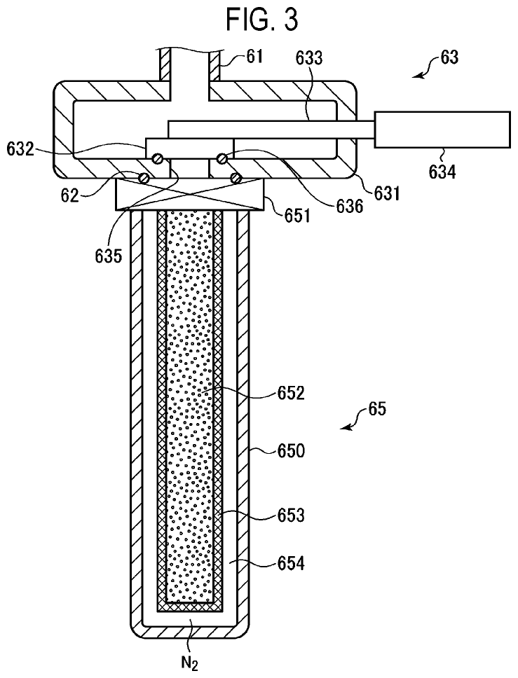

FIG. 3 is a cross-sectional view illustrating a specific example of the powder raw material replenishing mechanism 60. FIG. 3 illustrates a detailed structure of the opening/closing part 63 and the powder raw material cartridge 65 in this example.

As illustrated in FIG. 3, in this example, the opening/closing part 63 is constituted with a gate valve and includes a housing 631, a valve body 632, a piston 633, and an actuator 634.

The pipe 61 is connected to an upper portion of the housing 631. An opening 635 is formed in a bottom wall of the housing 631 so as to communicate with the powder raw material cartridge 65, and the connector 62 configured as a seal ring is provided around the opening 635 on a lower surface of the bottom wall. That is, the opening 635, which serves as the connection port of the connector 62, is oriented downward.

The valve body 632 is provided to be slidable horizontally in the interior of the housing 631. The piston 633 is attached to the valve body 632 and is advanced and retracted by the actuator 634, thus causing the valve body 632 to open and close the opening 635 by sliding thereof. An example of the actuator 634 may be a cylinder mechanism. A seal ring 636 is provided around the opening 635 on an upper surface of the bottom wall of the housing 631. Thus, when the valve body 632 closes the opening 635, sealing between the valve body 632 and the bottom wall of the housing 631 is implemented.

Further, the powder raw material cartridge 65 includes an elongated container 650 and an on-off valve 651 provided at an upper end of the container 650. An upper surface of the on-off valve 651 serves as a connection surface with respect to the connector 62. A filter 653 is provided inside the container 650 of the powder raw material cartridge 65 to divide the interior of the container 650 into an inner portion and an outer portion along an inner wall surface thereof. The outer portion serves as a carrier gas filling space 654 filled with a carrier gas, which is an N₂ gas (inert gas). The inner portion is filled with a powder raw material 652. The powder raw material and the inert gas may be filled without the filter 653. The on-off valve 651 remains closed except when replenishing the powder raw material from the powder raw material cartridge 65 to the powder raw material supply apparatus 20, and is configured to prevent the filled powder raw material from exposing to atmosphere during transportation or the like. The on-off valve 651 is not particularly limited, but a gate valve may be suitably used.

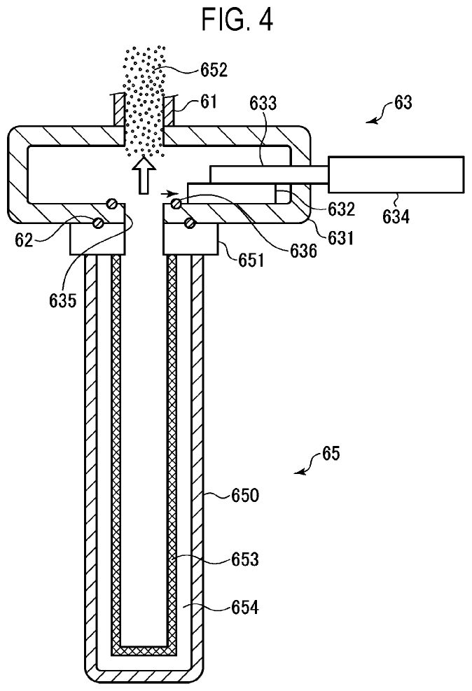

In this example, in the state where the interior of the pipe 61 is evacuated, the powder raw material cartridge 65 is connected to the connector 62. Thereafter, the on-off valve 651 is open. Further, as illustrated in FIG. 4, the valve body 632 is moved to open the opening/closing part 63 so that the powder raw material 652 inside the powder raw material cartridge 65 is transferred to the powder raw material supply apparatus 20 while being carried by the N₂ gas as an inert gas.

The controller 70 is constituted with a computer, and includes a main controller provided with a CPU, an input device, an output device, a display device, and a storage device (storage medium). The main controller controls operations of each component of the raw material gas supply system 100, such as valves, the vaporization apparatuses 10a and 10b, and the exhauster 67. The control of each component by the main controller is performed based on a control program stored in a storage medium (such as a hard disk, optical desk, semiconductor memory, etc.) embedded in the storage device. Processing recipes are stored as control programs in the storage medium, and the processing of the raw material gas supply system 100 is executed based on the processing recipes.

Next, an operation of the raw material gas supply system 100 configured as described above will be described.

In the raw material gas supply system 100, the powder raw material inside the powder raw material supply apparatus 20 is supplied to the vaporization apparatus 10a or 10b via the powder raw material supply piping section 30 to fill the container. Then, in the vaporization apparatus 10a or 10b, the supplied powder raw material is vaporized, and a raw material gas thus generated is supplied to the processing apparatus 200 via the raw material gas supply piping section 40. At this time, the raw material gas is transferred to the processing apparatus 200 by the carrier gas supplied from the carrier gas supplier 50. In the processing apparatus 200, for example, a film formation processing is performed on the substrate W.

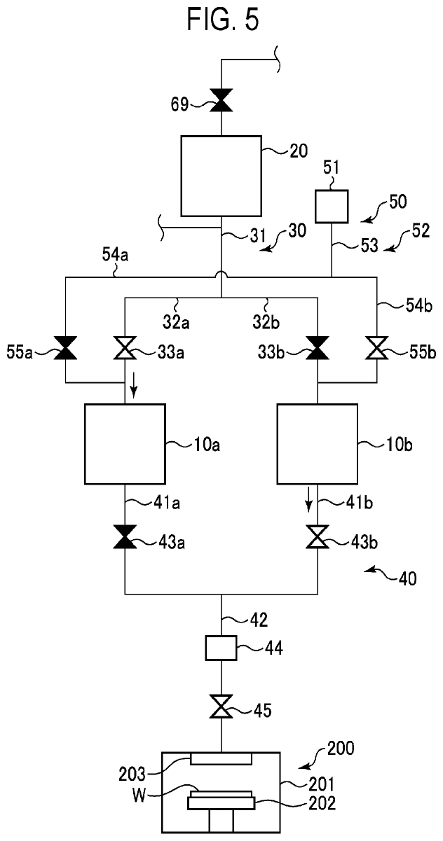

At this time, since two vaporization apparatuses 10a and 10b are provided, one may be used to vaporize the powder raw material while the other one is used to receive and store the powder raw material supplied thereto. An example thereof will be described with reference to FIG. 5. FIG. 5 illustrates an example in which the powder raw material is supplied to the vaporization apparatus 10a and is stored in the container thereof, while the vaporization apparatus 10b vaporizes the powder raw material stored in the container thereof to supply the raw material gas to the processing apparatus 200. In addition, in FIG. 5, the open state of the on-off valve is indicated with white, and the closed state thereof is indicated with black.

Specifically, the on-off valve 33a of the powder raw material supply piping section 30 is open to supply the powder raw material from the powder raw material supply apparatus 20 to the vaporization apparatus 10a and store the same in the container. At this time, the on-off valve 43a of the raw material gas supply piping section 40 and the on-off valve 55a of the carrier gas supplier 50 remain closed. On the other hand, with the on-off valve 43b of the raw material gas supply piping section 40 open, the powder raw material in the container of the vaporization apparatus 10b is vaporized, and the raw material gas thus generated is supplied to the processing apparatus 200. At this time, the on-off valve 33b of the powder raw material supply piping section 30 is closed to stop the supply of the powder raw material to the vaporization apparatus 10b, and the on-off valve 55b of the carrier gas supplier 50 is open to supply the carrier gas to the vaporization apparatus 10b, thus transferring the raw material gas in the vaporization apparatus 10b.

When the powder raw material stored in the container of the vaporization apparatus 10b falls below a certain amount, the on-off valves are switched, so that the powder raw material is supplied to the vaporization apparatus 10b and the raw material gas is supplied from the vaporization apparatus 10a to the processing apparatus 200 in the same manner.

The above operation is repeated. When the powder raw material in the powder raw material supply apparatus 20 falls below a certain amount, the powder raw material is replenished from the powder raw material replenishing mechanism 60 to the powder raw material supply apparatus 20.

Powder raw materials are susceptible to oxidation, and in particular, powder raw materials used in processes of manufacturing fine semiconductor devices have a negative effect on the process results due to oxidation. For this reason, the oxygen content of powder raw materials is strictly controlled. Therefore, when replenishing the powder raw material to the powder raw material supply apparatus 20, it is necessary to prevent the powder raw material from exposing to atmosphere. In the related art, measures for purging pipes have been adopted when replenishing powder raw materials. However, in recent years, quality requirements for powder raw materials have become stricter, and there is a demand for more rigorous techniques to prevent the exposure of the powder raw materials to the atmosphere. Patent Document 1 discloses that the raw material cartridge filled with the powder raw material is mounted when replenishing the powder raw material, but does not describe specific measures for strictly preventing the exposure of the powder raw material to the atmosphere during powder replenishment.

In contrast, in the present embodiment, the powder raw material replenishing mechanism 60 is configured to include the pipe 61 having one end connected to the powder raw material supply apparatus 20, the connector 62 and the opening/closing part 63 which are provided at the side of the other end of the pipe 61, the vacuum exhauster 64 for evacuating the pipe 61, and the powder raw material cartridge 65 connected to the connector 62. Further, in the state where the interior of the pipe 61 is evacuated by the vacuum exhauster 64 such that the interior of the pipe 61 is kept in a vacuum, the powder raw material cartridge 65 is connected to the connector 62, and the opening/closing part 63 is open such that the pipe 61 and the powder raw material cartridge 65 are in communication with each other. Thus, in a state where the powder raw material cartridge 65 is in close contact with the connector 62, the powder raw material inside the powder raw material cartridge 65 is supplied to the powder raw material supply apparatus 20 while being carried by the inert gas inside the powder raw material cartridge 65. Therefore, when transferring the powder raw material from the powder raw material cartridge 65 to the powder raw material supply apparatus 20, it is possible to strictly prevent the exposure of the powder raw material to the atmosphere.

Further, since the connector 62 is provided at the opening/closing part 63, when transferring the powder raw material inside the powder raw material cartridge 65 with the opening/closing part 63 open, it is possible to more reliably prevent the powder raw material from being brought into contact with air. Further, since the connector 62 is attached to the bottom of the opening/closing part 63 such that the connection port of the connector 62 is oriented downward, the powder raw material cartridge 65 is connected to the connector 62 while a transfer port of the powder raw material cartridge 65 is oriented upward, so that the powder raw material inside the powder raw material cartridge 65 is transferred so as to be drawn up into the pipe 61. This makes it possible to suppress the powder raw material from adhering to the sealing surface of the opening/closing part 63 and thus reduce generation of external leakage. Further, since a gate valve is used as the opening/closing part 63, an opening area when the opening/closing part 63 is open may be increased, which is advantageous for transferring the powder raw material. Further, the on-off valve 651 is provided at one end of the powder raw material cartridge 65. Thus, by closing the on-off valve 651 when transporting the powder raw material cartridge 65, the interior of the powder raw material cartridge 65 may be hermetically sealed. This makes it possible to prevent the exposure of the powder raw material to the atmosphere.

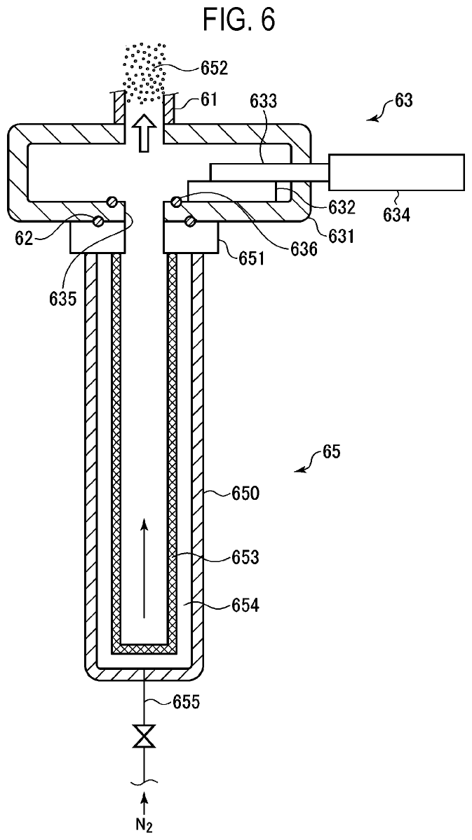

As illustrated in FIG. 6, the powder raw material cartridge 65 may be provided with a carrier gas line 655. When transferring the powder raw material, an inert gas, for example, an N₂ gas may be supplied as a carrier gas from the carrier gas line 655 into the powder raw material cartridge 65. This makes it possible to more reliably transfer the powder raw material inside the powder raw material cartridge 65.

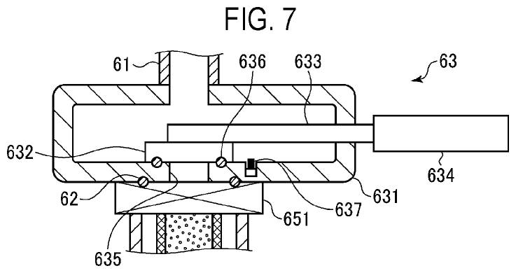

Further, as illustrated in FIG. 7, a brush 637 may be provided in a movement area of the valve body 632 on the upper surface of the bottom wall of the housing 631 of a gate valve constituting the opening/closing part 63. This makes it possible to clean a sealing surface of the valve body 632 when opening and closing the valve body 632 and more reliably prevent external leakage.

### Other Applications

Although the embodiments have been described above, the embodiments disclosed herein should be considered to be exemplary and not restrictive in all respects. The above embodiments may be omitted, replaced, or modified in various ways without departing from the scope and spirit of the appended claims.

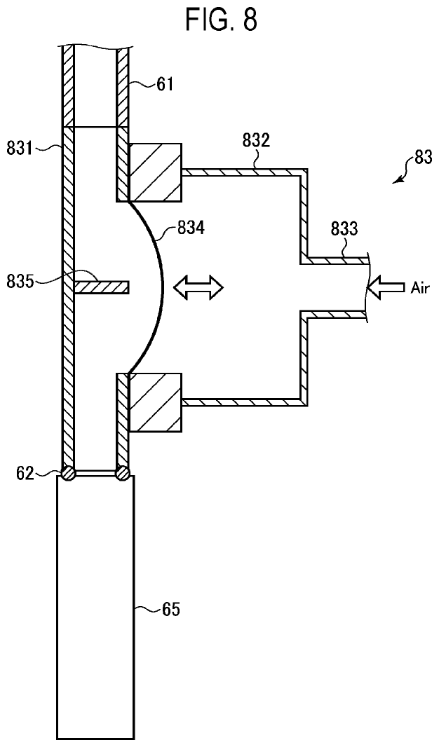

For example, the above embodiment has illustrated an example of using, as the opening/closing part 63, a gate valve capable of increasing the opening area thereof in the open state, but the opening/closing part is not limited thereto as long as it is capable of transferring the powder raw material in the open state. For example, the opening/closing part 83 may be configured as a diaphragm valve as illustrated in FIG. 8. The opening/closing part 83 of FIG. 8 includes a transfer path 831, a housing 832, an air inlet/outlet port 833, a diaphragm 834, and a valve seat 835. The transfer path 831 has one end connected to the pipe 61 and the other end formed with the connector 62. The valve seat 835 is provided in the middle of the transfer path 831. The housing 832 is provided adjacent to the transfer path 831, and the diaphragm 834 partitions between the transfer path 831 and the housing 832. The air inlet/outlet port 833 is provided in the housing 832. The diaphragm 834 makes contact with and moves away from the valve seat 835 by introducing and discharging air from the air inlet/outlet port 833 to the housing 832, thereby opening and closing the transfer path 831. However, the diaphragm valve is impossible to provide a large opening area in the open state like the gate valve. Thus, the carrier gas may be supplied to the transfer path 831 to facilitate the transfer of the powder raw material.

Further, the above embodiment has illustrated an example in which two vaporization apparatuses are provided as the raw material gas supply system, but one vaporization apparatus may be provided. However, by providing two vaporization apparatuses, it is possible to supply the powder raw material to one apparatus while the other apparatus performs a process of vaporizing the powder raw material. This improves throughput.

Furthermore, the above embodiment has illustrated the film forming apparatus as the processing apparatus, but the processing apparatus is not limited thereto as long as it performs a processing using a raw material gas.

### EXPLANATION OF REFERENCE NUMERALS

10a, 10b: vaporization apparatus, 20: powder raw material supply apparatus, 30: powder raw material supply piping section, 40: raw material gas supply piping section, 50: carrier gas supplier, 60: powder raw material replenishing apparatus, 61: pipe, 62: connector, 63: opening/closing part, 64: vacuum exhauster, 65: powder raw material cartridge, 100: raw material gas supply system, 200: processing apparatus, 651: on-off valve, 652: powder raw material, 653: filter, 654: carrier gas filling space, W: substrate

1-12. (canceled)

13. A powder raw material replenishing mechanism for replenishing a powder raw material to a powder raw material supply apparatus that supplies the powder raw material to a vaporization apparatus in a raw material gas supply system that supplies a raw material gas, generated by vaporizing the powder raw material with the vaporization apparatus, to a processing apparatus, the powder raw material replenishing mechanism comprising:
a pipe having a first end connected to the powder raw material supply apparatus;
a powder raw material cartridge filled with the powder raw material;
a connector provided at a side of a second end of the pipe such that the powder raw material cartridge is detachably connected to the connector;
an opening/closing part provided at the side of the second end of the pipe and configured to open and close between the pipe and the powder raw material cartridge; and
a vacuum exhauster configured to evacuate an interior of the pipe and keep the interior of the pipe at a vacuum,
wherein, in a state where the interior of the pipe is kept at the vacuum by the vacuum exhauster, the powder raw material cartridge is connected to the connector, and the opening/closing part is opened in the state so that the powder raw material inside the powder raw material cartridge is transferred to the powder raw material supply apparatus.

14. The powder raw material replenishing mechanism of claim 13, wherein the connector is provided at the opening/closing part.

15. The powder raw material replenishing mechanism of claim 14, wherein the opening/closing part is constituted with a gate valve including a housing connected to the pipe and having an opening that serves as a connection port of the connector, a valve body configured to be slidable inside the housing to open and close the opening, and an actuator configured to slide the valve body.

16. The powder raw material replenishing mechanism of claim 15, wherein the opening/closing part further includes a brush provided in the housing to clean a sealing surface of the valve body when the valve body slides.

17. The powder raw material replenishing mechanism of claim 14, wherein a connection port of the connector is oriented downward.

18. The powder raw material replenishing mechanism of claim 17, wherein the powder raw material cartridge includes an on-off valve provided at an end portion of the connector, and
wherein when the on-off valve is open, a replenishment of the powder raw material is performed, and when the on-off valve is closed, an interior of the powder raw material cartridge is hermetically sealed.

19. The powder raw material replenishing mechanism of claim 17, wherein a carrier gas composed of an inert gas is included in the powder raw material cartridge so that the powder raw material is transferred from the powder raw material cartridge while being carried by the carrier gas.

20. The powder raw material replenishing mechanism of claim 19, wherein the powder raw material cartridge includes a filter configured to divide the interior of the powder raw material cartridge into an inner portion and an outer portion, and
wherein the outer portion serves as a carrier gas filling space filled with the carrier gas and the inner portion is filled with the powder raw material.

21. The powder raw material replenishing mechanism of claim 20, wherein the powder raw material cartridge is connected to a carrier gas supply line configured to supply the carrier gas composed of the inert gas.

22. The powder raw material replenishing mechanism of claim 17, wherein the vacuum exhauster evacuates the interior of the pipe from a side of the powder raw material supply apparatus to keep the interior of the pipe at the vacuum.

23. The powder raw material replenishing mechanism of claim 13, wherein the powder raw material cartridge includes an on-off valve provided at an end portion of the connection surface side, and
wherein when the on-off valve is open, a replenishment of the powder raw material is performed, and when the on-off valve is closed, an interior of the powder raw material cartridge is hermetically sealed.

24. The powder raw material replenishing mechanism of claim 13, wherein a carrier gas composed of an inert gas is included in the powder raw material cartridge so that the powder raw material is transferred from the powder raw material cartridge while being carried by the carrier gas.

25. The powder raw material replenishing mechanism of claim 13, wherein the vacuum exhauster evacuates the interior of the pipe from a side of the powder raw material supply apparatus to keep the interior of the pipe at the vacuum.

26. A raw material gas supply system for supplying a raw material gas to a processing apparatus that processes a substrate, comprising:
a vaporization apparatus configured to vaporize a powder raw material to generate the raw material gas;
a powder raw material supply apparatus configured to supply the powder raw material to the vaporization apparatus;
a powder raw material supply piping section configured to supply the powder raw material from the powder raw material supply apparatus to the vaporization apparatus;
a raw material gas supply piping section configured to supply the raw material gas from the vaporization apparatus to the processing apparatus; and
a powder raw material replenishing mechanism configured to replenish the powder raw material to the powder raw material supply apparatus,
wherein the powder raw material replenishing mechanism includes:
a pipe having a first end connected to the powder raw material supply apparatus;
a powder raw material cartridge filled with the powder raw material;
a connector provided at a side of a second end of the pipe such that the powder raw material cartridge is detachably connected to the connector;
an opening/closing part provided at the side of the second end of the pipe and configured to open and close between the pipe and the powder raw material cartridge; and
a vacuum exhauster configured to evacuate an interior of the pipe and keep the interior of the pipe at a vacuum, and
wherein, in a state where the interior of the pipe is kept at the vacuum by the vacuum exhauster, the powder raw material cartridge is connected to the connector, and the opening/closing part is opened in the state so that the powder raw material inside the powder raw material cartridge is transferred to the powder raw material supply apparatus.

27. A powder raw material replenishing method of replenishing a powder raw material to a powder raw material supply apparatus that supplies the powder raw material to a vaporization apparatus in a raw material gas supply system that supplies a raw material gas, generated by vaporizing the powder raw material with the vaporization apparatus, to a processing apparatus, the powder raw material replenishing method comprising:
providing a powder raw material replenishing mechanism including: a pipe having a first end connected to the powder raw material supply apparatus; a powder raw material cartridge filled with the powder raw material; a connector provided at a side of a second end of the pipe such that the powder raw material cartridge is detachably connected to the connector; an opening/closing part provided at the side of the second end of the pipe and configured to open and close between the pipe and the powder raw material cartridge; and a vacuum exhauster configured to evacuate an interior of the pipe and keep the interior of the pipe at a vacuum;
keeping an interior of the pipe at a vacuum by the vacuum exhauster;
connecting the powder raw material cartridge to the connector; and
opening the opening/closing part to transfer the powder raw material inside the powder raw material cartridge to the powder raw material supply apparatus.
